(19) United States
(12) Patent Application Publication
(10) Pub. No.: US 2003/0001626 A1
(43) Pub. Date: Jan. 2, 2003

(54) Detection of voltage amplitude using current

(75) Inventors: Robert Andrew Kertis, Rochester, MN (US); Peter John Windler, Fort Collins, CO (US)

Correspondence Address: Robert R. Williams, IBM Corporation, Dept. 917, 3605 Highway 52 North, Rochester, MN, 55901-7829, US

(73) Assignee: INTERNATIONAL BUSINESS MACHINES CORPORATION, ARMONK, NY

(21) Appl. No.: 09/894,265

(22) Filed: Jun. 28, 2001

(51) Int. Cl. H03K 5/153

(52) U.S. Cl. 327/78

(57) ABSTRACT

A circuit is disclosed which uses less power and is responsive to high frequencies which can detect if a signal has sufficient amplitude. The signal of interest is input to an active semiconductor device. The other inputs to the active device are set by the value of the amplitude which the signal must be less than/greater than. The circuit is especially useful in an oscillator which generates high frequency clock signals to determine if the clock signals have sufficient amplitude to drive the electronics.

### FIELD OF THE INVENTION

The present invention relates generally to the field of detecting the amplitude of an electronic signal, and more particularly, the invention is directed to an apparatus and a method to detect when an electrical voltage signal has exceeded a specified voltage using current comparisons.

### BACKGROUND OF THE INVENTION

In the world of electronic data transfer, the signals must have sufficient signal strength or amplitude otherwise the data may not be detected or errors may occur in the transmission and receipt of the data. Data is transferred at an increasingly faster and faster rate such that optical signals are communicated at a rate of two gigahertz or more and electrical digital signals are transferred on the order of four gigahertz or more. This data must be detected and interpreted correctly. Often, the receiver generates its own clock signals at the frequency of the data and expects to receive data at that clock frequency. Voltage controlled oscillators are often used to generate reliable clock frequencies for a myriad of applications. A voltage controlled oscillator (VCO) is simply a circuit that generates an oscillating signal at a frequency proportional to an externally supplied voltage. VCOs are basic building blocks of many electronic systems especially phase-locked loops and may be found in computer disk drives, wireless electronic equipment such as cellular telephones, and other systems in which oscillation frequency is controlled by an applied tuning voltage.

Because of the generation of phase noise and jitter by ring oscillators and because of the sensitivity of the multivibrator or relaxation oscillator to thermal effects, experts in the industry use an oscillator based on inductors and capacitors, the LC oscillator, which generates less phase noise and jitter and is more temperature-stable. The output of the LC oscillator may be amplified, conditioned, mixed, and/or prescaled to generate clock signals in a variety of applications as mentioned above. When the LC oscillator is used to generate clock signals, an amplitude monitor may be connected to the output of the LC oscillator to determine if the output signal has sufficient amplitude to generate reliable clock signals.

Previously, the amplitude monitors used in phase lock-loop (PLL) include a peak-hold circuit such as shown in FIG. 1. The output of the LC oscillator is input into the peak-hold circuit, and particularly to the base of an npn bipolar transistor 120. The bandwidth of the npn bipolar transistor helps the peak-hold circuit to function properly. The voltage at node B 125 follows the input voltage A 110. The emitter of the npn bipolar transistor is connected to a capacitor 140 which holds the peak voltage at node B 125. When the voltage at node B 125 is greater than the reference voltage 150, both of which are input to a comparator, the comparator transitions. This reference voltage 150 is selected to always be more than sufficient for a frequency divider or prescaler to function properly. Thus, by detecting the transition, it is determined that the input signal A 110 has a sufficient amplitude.

The upper graph of FIG. 1 illustrates the input signal A 110 as a function of time and the lower graph represents the voltage at node B 125. There is a short time required for the capacitor 140 to charge as represented in the shoulder of the signal at node B 125. After the capacitor is charged, the voltage at node B 125 levels off as is shown in the lower graph of FIG. 1.

In CMOS technology, however, merely replacing the npn bipolar transistor with a n-type field effect transistor (nfet) does not give the same results as the peak-hold circuit. The amplitude is significantly attenuated at the output of the transistor;

temperature sensitivity increases, and bandwidth is reduced. There thus is a need in the industry, therefore, to be able to detect if a signal has sufficient signal strength using CMOS technology.

### SUMMARY OF THE INVENTION

These needs and others are met by an embodiment of the present invention, herein disclosed as a circuit to monitor amplitude of an input signal, comprising: an active device to provide a current representative of the amplitude of an input signal connected to the active device, a reference voltage connected to the active device, a current source connected to the active device, and a comparator connected to a node between the active device and the current source; wherein when the input signal is less than the reference voltage minus a threshold voltage of the active device, the active device conducts current representative of the input signal, and wherein when the conducting current is greater then the current output from the current source, the voltage at a node between the current source and the active device transitions, and wherein when the voltage at the node transitions past a second reference voltage input to the comparator, an output of the comparator will transition. The active element may be at least one field effect transistor whose gate is electrically connected to the reference voltage and whose drain is electrically connected to the input signal and whose source is connected to the node, such as an n-type field effect transistor or a p-type field effect transistor. The active device may also be a bipolar transistor. The current source may be tunable, and may be a digital-to-analog current source.

The invention may also be considered a phase-locked loop (PLL) circuit comprising: a charge pump, a capacitor connected to the charge pump, a varactor driver connected to the charge pump across the capacitor, an oscillator to generate an output signal, an amplitude monitor to receive the output signal to determine if the output signal from the oscillator has sufficient amplitude, the amplitude monitor further comprising a transistor to provide a current representative of the amplitude of the output signal connected to the drain of the transistor, a reference voltage connected to the gate of the transistor, a tunable digital-to-analog current source connected to the source of transistor through a node between the transistor and the current source, a comparator connected to the node wherein when the output signal has an amplitude less than the reference voltage minus a threshold voltage of the transistor, the transistor conducts current representative of the output signal, and further wherein when the current through the transistor is greater then the current output from the current source, the voltage at a node between the current source and the transistor decreases, and when the voltage at the node is less than a second reference voltage input to the comparator, an output of the comparator will transition; an amplifier and a prescaler also connected to the output signal of the oscillator to generate a clock signal; and a timing detector to correct the frequency and/or phase of the clock signal.

The invention may further be considered an amplitude detector, comprising a means to generate a current representative of the amplitude of an incoming signal, a means to generate a reference current, a means to create a voltage difference between the current representative of the amplitude of the incoming signal and the reference current, and a means to transition an output signal when the current representative of the amplitude of the incoming signal is greater than the reference current.

The invention is also a method to detect when the amplitude of an incoming signal is greater than a reference voltage, comprising the steps of inputting a voltage to an active device to turn on the active device, inputting a signal whose amplitude is to be monitored to the active device such that when the amplitude is at a certain level, the active device conducts, providing a reference current to a node, and triggering an output signal when the current from the active device is greater than/less than the reference current. The active device may be an n-type field effect transistor, p-type field effect transistor, or a bipolar transistor.

The recitation herein of a list of inventive features which are met by various embodiments of the present invention is not meant to imply or suggest that any or all of these features are present as essential or necessary features, either individually or collectively, in the most general embodiment of the present invention or in any of its more specific embodiments.

### DESCRIPTION OF THE FIGURES

The invention, both as to organization and method of practice, together with further objects and advantages thereof, may best be understood by reference to the following description taken in connection with the accompanying drawings in which:

FIG. 1 is a simplified block diagram of a prior art peak-hold circuit using an npn bipolar transistor to monitor the output of an LC oscillator.

FIG. 2 is a simplified block diagram of a PLL with an amplitude monitor connected to the output of the LC oscillator.

FIG. 3 is a schematic circuit diagram of a circuit which can be used as an amplitude monitor in accordance with an embodiment of the invention. It is suggested that FIG. 3 be printed on the face of the patent.

FIGS. 4a and 4b are simplified wave diagrams showing how the circuit of FIG. 3 can be programmed to detect different voltage levels in accordance with different embodiments of the invention.

FIG. 5 is an embodiment of the amplitude monitor of the invention using an npn bipolar transistor.

FIG. 6 is an embodiment of the amplitude monitor of the invention using a p-type field effect transistor.

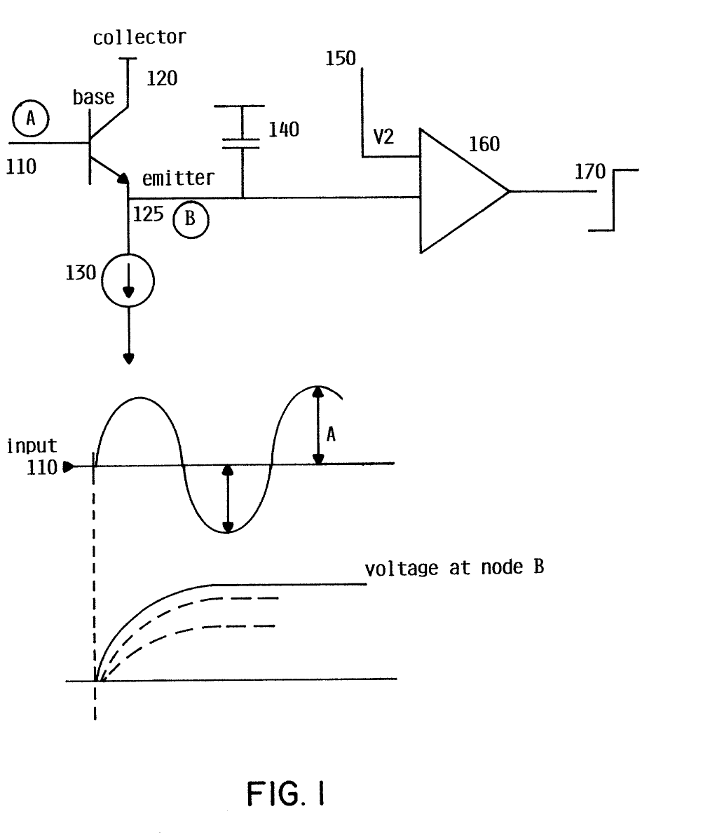

### DETAILED DESCRIPTION OF THE INVENTION

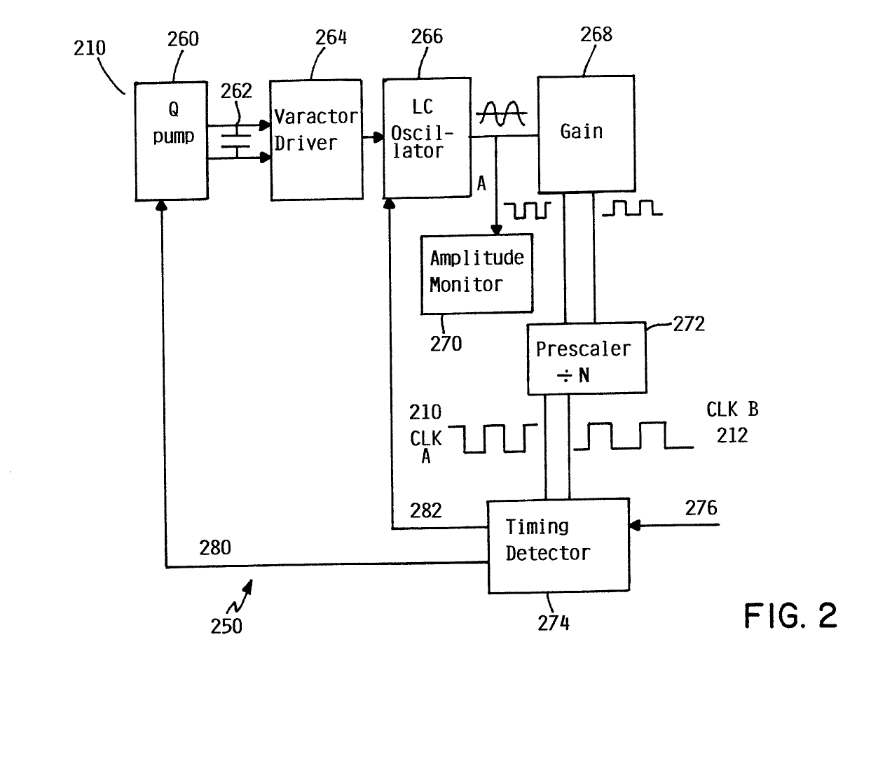

With reference to FIG. 2, there is shown a PLL circuit 250 incorporating an amplitude monitor having an embodiment of the circuit described herein using current to monitor the amplitude of a signal, in this case, the signal output of an LC oscillator. In the PLL, the charge pump 260 provides a current to the loop filter capacitor 262 which then charges/discharges the voltage on it. Voltage is provided to the varactor driver 264 which outputs a voltage to the oscillator circuit 266. The oscillator circuit 266 may be a ring oscillator or other LC sinusoidal oscillator. As before, the output of the oscillator circuit 266 whose frequency is proportional to the input voltage is amplified 268 and prescaled 272 to achieve the desired true and complement clock signals 210 and 212. These clock signals 210 and 212 are determined by the loop filter capacitor 262 and are referred to as the oscillation or operating clock signal. Illustrated here are two signals, the true and complement clock 210 and 212, but the circuit may generate only one clock signal or numerous clock signals. The use of two clock signals is an example of only one embodiment.

A timing detector 274 has inputs which are the clock frequency 210 and 212 and data 276 which compares the frequency and the phase of the data 276 to the clocks 210 and 212. Rather than providing only a frequency correction signal 280, an independent path for correction of the phase 282 may provide feedback directly to the oscillator circuit 266 to also adjust the phase of the clock signals in accordance with U.S. Ser. No. 09/696,514 entitled Phase Shift Control for Voltage Controlled Oscillator, filed Oct. 25 2000, which application is commonly owned by the assignee herein and which is hereby incorporated by reference in its entirety.

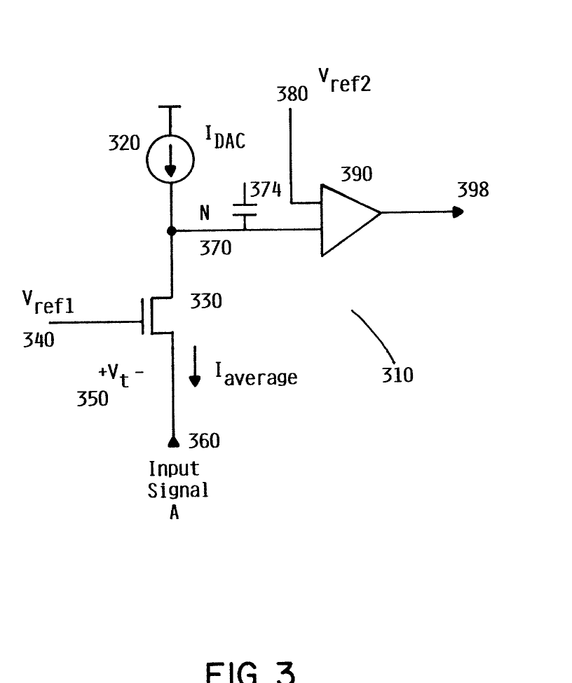

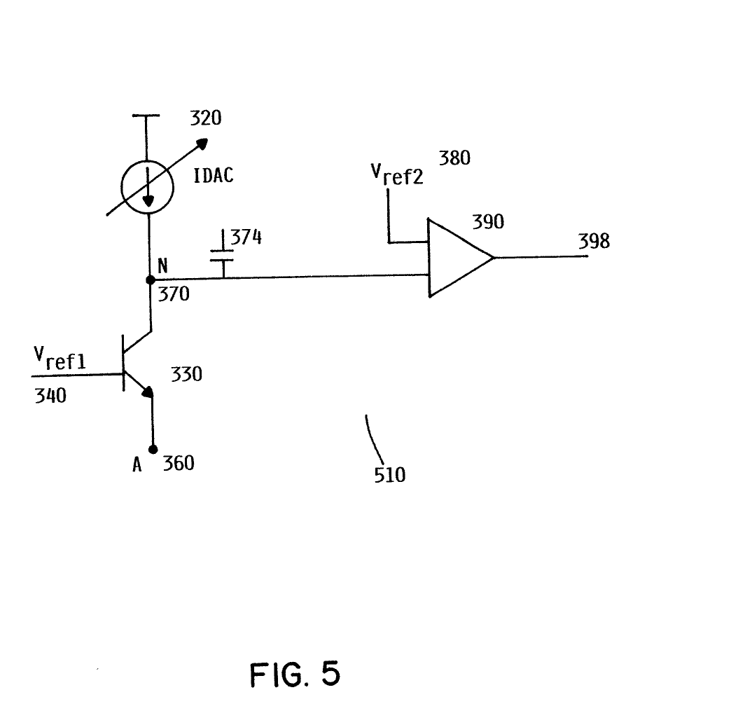

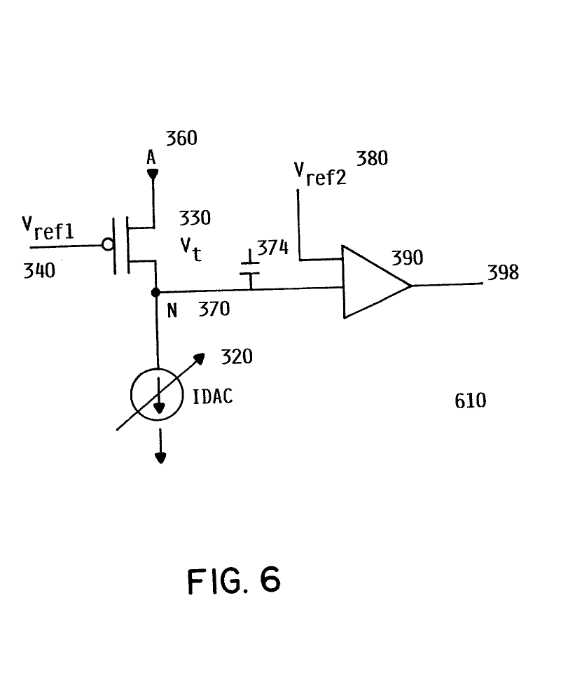

With reference to FIG. 3 therein is one embodiment of a circuit which can be used in the amplitude monitor 270. While one embodiment of the invention is described herein as detecting the level of the output of a LC oscillator, it should be understood that the invention is applicable in any circuit where it is desirable to detect if the signal amplitude is sufficient to a voltage set by the parameters of the circuit. The parameters of the circuit are set to ensure that the signal has sufficient amplitude to be used in other circuits, such as clock generators, etc. The circuit comprises an active device 330 controlled by a reference voltage 340. The active device 330 in FIG. 3 is an nfet whose gate is controlled by a reference voltage and it should be noted that other devices, such as a pfet or a bipolar, can be used as will be discussed with respect to FIGS. 5 and 6. The active device 330 is characterized such that it has gain and can turn on/off and generates a current output in response to a voltage input as discussed.

The active device may require a threshold voltage Vₜ 350 which is inherently characteristic of the device 330 to conduct current. Also input to the active device is the input signal 360 whose amplitude on a common mode voltage must exceed a critical voltage detectable by the circuit described herein. In the example shown, the input signal 360 is output from the LC oscillator 266 of FIG. 2. The circuit 310 has a current source 320 to provide current input to node N 370. Preferably current source 320 is a digital-to-analog current source to allow tunability. A voltage exists at Node N 370 resulting from the difference between the current conducted through the active device 330 and the current generated by the current source 320. A high voltage exists at node N 370 when the current from the current source is greater than the current through the active device. The voltage at node N 370 is then smoothed by capacitor 374 which controls the ripple and then input to a comparator 390 and when the voltage at node N 370 is less than a second reference voltage 380, an output signal 398 will transition.

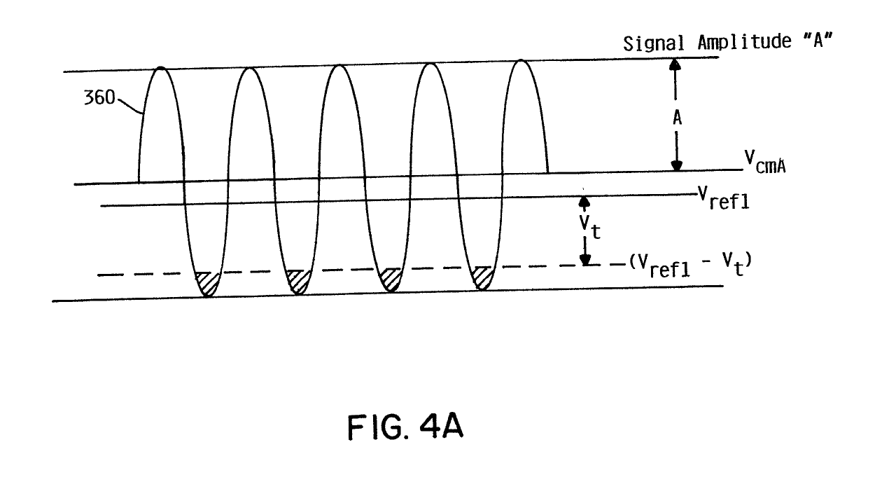

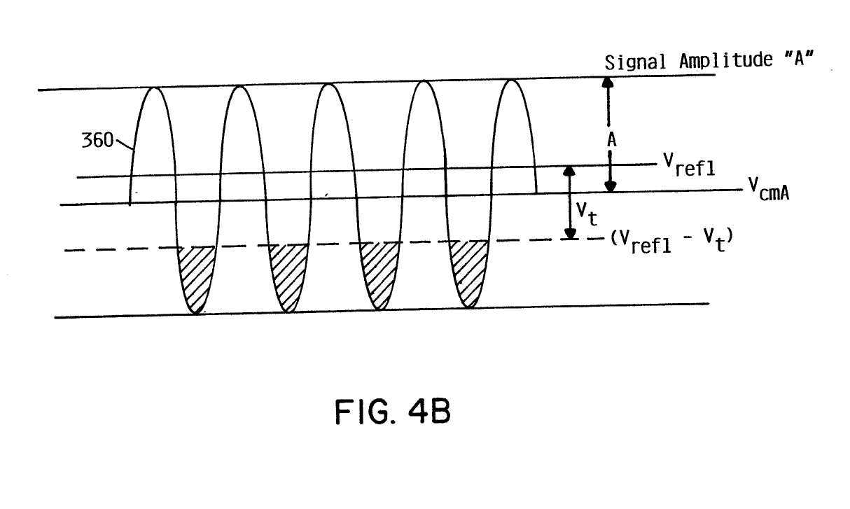

The circuit works best by selection of the active device 330 and the current source 320 so they are specific to the application. FIGS. 4a and 4b, when viewed in conjunction with FIG. 3, illustrate the principles of operation of the current monitor when the active device is the nfet transistor. The signal of interest, input signal 360, may be carried on a common mode voltage, V_{CMA}, which may be the same or different than the reference voltage, as shown in FIGS. 4a and 4b. Current flows through transistor 330 when the amplitude of the input signal 360 is less than the difference between V_{ref1}, and Vₜ, i.e., V_{signal} 360<(V_{ref1} 340−Vₜ 350). The current is proportional to [(V_{ref1} 340−Vₜ 350)−V_{signal} 360]. Given FIGS. 4a and 4b, the current through the transistor is proportional to the shaded area under the curve divided by time to yield an average current. If the current through the transistor is greater than the current from the current source 320, the voltage at node N 370 drops and cause a transition of the output 398 of comparator 390. Thus, the amplitude needed to trip the comparator 390 is dependent upon the inherent characteristics of the active device, the first input reference voltage to the active device, and the current derived from the current source.

In FIG. 4a, the value of Vₜ, i.e., the threshold voltage required for the active device, is a higher percentage of the signal amplitude A than the value of Vₜ, shown in FIG. 4b. The common mode signal voltage V_{CMA} may be on the order of 1.8 volts and the amplitude of the input signal may transition between approximately 1 volt to 2.6 volts. These values are not intended to be limiting and are examples of CMOS voltage levels. Given other CMOS and/or other technologies, other voltage and current levels will be achieved as will be known by one skilled in the art.

FIG. 5 is an embodiment of the current monitor using a npn bipolar transistor instead of an nfet transistor. This embodiment is similar in operation to that described with respect to FIG. 3. FIG. 6 is yet another embodiment of the current monitor wherein the active device is a p-type field effect transistor (pfet) 330. In FIG. 6, when V_{signal} 360 is greater than the difference between V_{ref1} 340 and the pfet's threshold voltage Vₜ, the pfet 330 will conduct current. When the conducting current is greater than the current output from the digital-to-analog current source 320, the voltage at node N 370 increases. When this voltage at node N 370 is greater than the voltage at V_{ref2} 380, both of which are input to the comparator 390, the output 398 of the comparator 390 will transition. The active device in any of these embodiments could be manufactured with other semiconductor technologies, such as GaAs, other Group III/V, Group II/VI semiconductors, silicon-on-insulator technologies, vacuum technologies, etc. The principles of the invention is to use an active current device which, when the signal amplitude is at the appropriate levels, will conduct more current than that provided by a stable current source, such as a digital-to-analog current source, which in turn causes the output of a comparator to transition.

The invention as described is particularly useful in disk drive and other applications where the data on the disk or other signal of interest and the oscillator are at very high frequencies. While the invention has been described in detail herein in accordance with certain preferred embodiments thereof, many modifications and changes therein may be effected by those skilled in the art. Accordingly, it is intended by the appended claims to cover all such modifications and changes as fall within the true spirit and scope of the invention.

What is claimed is:

1. A circuit to monitor amplitude of an input signal, comprising:
(a) an active device to provide a current representative of the amplitude of an input signal connected to the active device;
(b) a reference voltage connected to the active device;
(c) a current source connected to the active device;
(d) a comparator connected to a node between the active device and the current source;
wherein when the input signal is less than the reference voltage minus a threshold voltage of the active device, the active device conducts current representative of the input signal, and
wherein when the conducting current is greater then the current output from the current source, the voltage at a node between the current source and the active device transitions, and
wherein when the voltage at the node transitions past a second reference voltage input to the comparator, an output of the comparator will transition.

2. The circuit of claim 1, wherein the active element further comprises at least one field effect transistor whose gate is electrically connected to the reference voltage and whose drain is electrically connected to the input signal and whose source is connected to the node.

3. The circuit of claim 2, wherein the active device is an n-type field effect transistor.

4. The circuit of claim 2, wherein the active device is a p-type field effect transistor.

5. The circuit of claim 1, wherein the active device is an bipolar transistor.

6. The circuit of claim 2, wherein the current source is tunable.

7. The circuit of claim 6, wherein the tunable current source is a digital-to-analog current source.

8. A PLL circuit, comprising:
(a) a charge pump;
(b) a capacitor connected to the charge pump;
(c) a varactor driver connected to the charge pump across the capacitor;
(d) a LC oscillator to generate an output signal;
(e) an amplitude monitor to receive the output signal to determine if the output signal has sufficient amplitude, the amplitude monitor further comprising a transistor to provide a current representative of the amplitude of the output signal connected to the drain of the transistor, a reference voltage connected to the gate of the transistor, a tunable digital-to-analog current source connected to the source of transistor through a node between the transistor and the current source, a comparator connected to the node wherein when the output signal has an amplitude less than the reference voltage minus a threshold voltage of the transistor, the transistor conducts current representative of the output signal, and further wherein when the current through the transistor is greater then the current output from the current source, the voltage at a node between the current source and the transistor decreases, and when the voltage at the node is less than a second reference voltage input to the comparator, an output of the comparator will transition;
(f) an amplifier and a prescaler also connected to the output signal to generate a clock signal; and
(g) a timing detector to correct the frequency and/or phase of the clock signal.

9. An amplitude detector, comprising:
(a) means to generate a current representative of the amplitude of an incoming signal;
(b) means to generate a reference current;
(c) means to create a voltage difference between the current representative of the amplitude of the incoming signal and the reference current;
(d) means to transition an output signal when the current representative of the amplitude of the incoming signal is greater than the reference current.

10. A method to detect when the amplitude of an incoming signal is greater than a reference voltage, comprising:
(a) inputting a voltage to an active device to turn on the active device;
(b) inputting a signal whose amplitude is to be monitored to the active device such that when the amplitude is at a certain level, the active device conducts;
(c) providing a reference current to a node;
(d) triggering an output signal when the current from the active device is greater than/less than the reference current.

11. The method of claim 1 0, wherein the active device is an n-type field effect transistor.

12. The method of claim 10, wherein the active device is a p-type field effect transistor.

13. The method of claim 10, wherein the active device is an bipolar transistor.
